(19) United States
(12) Patent Application Publication
(10) Pub. No.: US 2023/0013653 A1
(43) Pub. Date: Jan. 19, 2023

(54) MEMORY DEVICE AND METHOD FOR FORMING SAME

(71) Applicant: CHANGXING MEMORY TECHNOLOGIES, INC., Hefei City (CN)

(72) Inventor: Yexiao YU, Hefei (CN)

(21) Appl. No.: 17/512,903

(22) Filed: Oct. 28, 2021

Related U.S. Application Data
(63) Continuation of application No. PCT/CN2021/117093, filed on Sep. 8, 2021.

(30) Foreign Application Priority Data
Jul. 19, 2021 (CN) 202110812497.7

(51) Int. Cl. H01L 27/108

(52) U.S. Cl. CPC H01L 27/10888; H01L 27/10823; H01L 27/10876; H01L 27/10885

(57) ABSTRACT

A memory device and a method for forming the same are provided. A hard mask layer is formed on a semiconductor substrate; and then multiple parallel mask patterns extending in a third direction are formed on the semiconductor substrate by adopting self-aligned multi-patterning. Openings are arranged between the adjacent mask patterns. The surfaces of multiple drain regions and corresponding part of the isolation layer in the third direction are exposed by the openings.

### CROSS-REFERENCE TO RELATED APPLICATIONS

The present application is a U.S. continuation application of International Application No. PCT/CN2021/117093, filed on Sep. 8, 2021, which claims priority to Chinese Patent Application No. 202110812497.7, filed on Jul. 19, 2021. International Application No. PCT/CN2021/117093 and Chinese Patent Application No. 202110812497.7 are incorporated herein by reference in their entireties.

### TECHNICAL FIELD

The disclosure relates to the field of memory, in particular to a memory device and a method for forming the same.

### BACKGROUND

Dynamic random access memory (DRAM), which includes multiple memory cells, is a semiconductor memory device commonly used in computers. The memory cell typically includes a capacitor and a transistor. In the transistor, a gate is connected to a word line, a drain region is connected to a bit line, and a source is connected to the capacitor. Voltage signals of the word line can control the transistors to be turned on or off, so as to read data information stored in the capacitor through the bit line, or write data information into the capacitors through the bit lines for storage.

In order to improve the integration of the memory structure, the transistors used in the DRAM usually are trench transistors. The specific structure of the trench transistor generally includes: a semiconductor substrate; active areas positioned in the semiconductor substrate; at least one trench positioned in the active area, a gate (or a word line structure) positioned in the trench; and a drain region and at least one source region of the active area which are positioned on two sides of the trench.

In the process for manufacturing DRAM in the related art, after the trench transistors are formed, BLCs (bitline contacts) connected to the drain regions of multiple transistors and bit lines connecting multiple BLCs also need to be formed.

In the related art, a LELE (Litho-Etch-Litho-Etch) double pattern technology is adopted for forming the BLCs. In this technology, first patterns are formed by conducting photoetching and etching for one time, and second patterns are formed by conducting photoetching and etching for another time, which together serve as an etching mask for forming the BLCs. However, the LELE double pattern technology has strict requirements on the accuracy of overlay. With reduction of the size, it is difficult for the LELE double pattern technology to realize the manufacturing of relatively small BLCs, and the edges of the patterns for forming the BLCs are rough, which will affect the performance of the device and increase the process cost.

### SUMMARY

The technical problem to be solved by the disclosure is to provide a novel method and a structure for forming relatively small BLCs, so as to reduce the roughness of the edges of the patterns for forming the BLCs, improve the performance of the device, and reduce the process cost.

To that end, some embodiments of the disclosure provide a method for forming a memory device, including the following operations.

A semiconductor substrate is provided, in which multiple separate active areas extending in a first direction are formed. The multiple active areas are isolated with each other by an isolation layer. Two parallel word lines extending in a second direction are formed in each active area and corresponding part of the isolation layer. Each active area is divided by two word lines thereof into a drain region positioned between the two word lines and source regions respectively positioned outside the word lines. A first acute angle is formed between the first direction and the second direction.

Multiple parallel mask patterns extending in a third direction are formed on the semiconductor substrate by adopting self-aligned multi-patterning. Openings are arranged between adjacent mask patterns. The surfaces of multiple drain regions and corresponding part of the isolation layer in the third direction are exposed by the openings.

The drain regions and the corresponding part of the isolation layer are etched through the openings by taken the multiple parallel mask patterns as a mask. Multiple trenches distributed in parallel are formed in the drain regions and the corresponding part of the isolation layer.

Strip-shaped bit line contact structures are formed by filling conductive layers in the trenches.

The strip-shaped bit line contact structures are divided to form multiple BLCs connected to corresponding drain regions.

Bit lines connecting the multiple BLCs are formed in a direction perpendicular to the second direction.

Some embodiments of the disclosure further provide a memory device formed by the method described above. The memory device includes the semiconductor substrate and the multiple parallel mask patterns.

Multiple separate active areas extending in the first direction are formed on semiconductor substrate. The active areas are isolated with each other by the isolation layer. The two parallel word lines extending in the second direction are formed in each active area and corresponding part of the isolation layer. Each active area is divided by the two word lines thereof into the drain region positioned between the two word lines and the source regions respectively positioned outside the word lines. The first acute angle being formed between the first direction and the second direction.

The multiple parallel mask patterns extend in the third direction and are formed on the semiconductor substrate by adopting self-aligned multi-patterning. The openings are arranged between the adjacent mask patterns. The surfaces of the multiple drain regions and corresponding part of the isolation layer in the third direction are exposed by the openings. The multiple parallel mask patterns are taken as a mask for etching the drain regions and the corresponding part of the isolation layer to form the multiple trenches distributed in parallel in the drain regions and the corresponding part of the isolation layer.

### BRIEF DESCRIPTION OF THE DRAWINGS

FIGS. 1 to 22 illustrate schematic structural diagrams of the process for forming a memory device according to embodiments of the disclosure.

### DETAILED DESCRIPTION

As described in the background, it is difficult for the current LELE double pattern technology to realize the manufacturing of relatively small BLCs, and the edges of patterns for forming BLCs are rough, which will affect the performance of the device and increase the process cost.

Therefore, the disclosure provides a memory device and a method for forming the same. The method for forming the memory device forms multiple parallel mask patterns extending in a third direction on a semiconductor substrate by adopting self-aligned multi-patterning. Openings are arranged between adjacent mask patterns. The surfaces of multiple drain regions and corresponding part of the isolation layer in the third direction are exposed by the openings. The mask patterns are formed by the self-aligned multi-patterning, so that the width or feature size of the openings between adjacent mask patterns can be relatively small and the surface roughness is relatively low. By doing so, when drain regions are subsequently etched through the openings to form trenches, the width or feature size of the corresponding trenches is relatively small and the surface roughness is relatively low, so that the width or feature size of bit line contact structures formed in the trenches is relatively small and the surface roughness is relatively low, thereby improving the performance of the memory device.

To make the objectives, features and advantages of the disclosure to be understood more clearly, specific implementations of the disclosure will be described in detail below with reference to the drawings. In the detailed description of the embodiments of the disclosure, the schematic diagrams will be partially enlarged not to a general scale for ease of illustration, and the schematic diagrams are merely for illustration, which should not limit the scope of disclosure herein. In addition, the actual production process should include three-dimensional dimensions of length, width and depth.

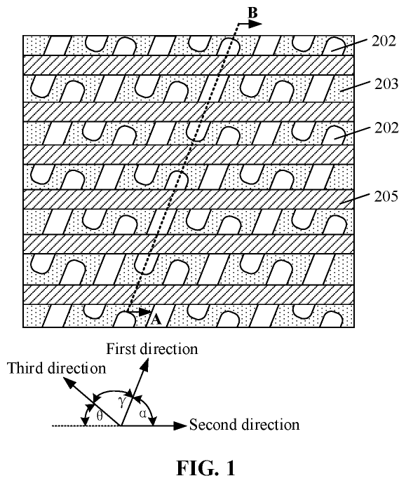

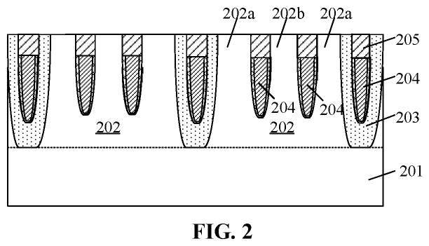

With reference to FIG. 1 and FIG. 2, FIG. 2 illustrates a schematic diagram from cross-sectional view of FIG. 1 along a cutting line AB. A semiconductor substrate 201 is provided. Multiple separate active areas 202 extending in a first direction are formed in the semiconductor substrate 201. The multiple active areas 202 are isolated with each other by an isolation layer 203. Two parallel word lines 204 extending in a second direction are formed in each active area 202 and corresponding part of the isolation layer 203 (with reference to FIG. 2, and only isolation protective layers 205 covering the surfaces of the word lines 204 are shown in FIG. 1). Each active area 202 is divided by the two word lines 204 into a drain region 202b positioned between the two word lines 204 and source regions 202a positioned respectively outside the word lines 204. A first acute angle α is formed between the first direction and the second direction.

The material of the semiconductor substrate 201 may be silicon (Si), germanium (Ge), or silicon germanium (GeSi), silicon carbide (SiC), may also be silicon on insulator (SOI) or germanium on insulator (GOI), or may be other materials, for example, III-V group compounds such as gallium arsenide. According to the embodiment, the material of the semiconductor substrate 201 is silicon. The semiconductor substrate is doped with certain doping ions as needed. The doping ions may be N-type doping ions or P-type doping ions. According to an embodiment, the doping includes well region doping and source/drain region doping.

According to an embodiment, the process for forming active areas 202 and the isolation layer 203 includes the following operations. A first mask layer (not shown in the drawings) is formed on a semiconductor substrate 201. The first mask layer is provided with multiple first mask openings distributed in parallel. The semiconductor substrate 201 is etched through the first mask openings by taking the first mask layer as a mask. Multiple separate strip-shaped active zones are formed in the semiconductor substrate 201. First trenches are arranged between adjacent strip-shaped active zones. The strip-shaped active zones are etched to form multiple second trenches in the strip-shaped active zones. The strip-shaped active zones are divided by the second trenches into multiple active areas 202. An isolation material is filled in the first trenches and the second trenches to form the isolation layer 203. The material of the isolation layer 203 may be silicon oxide or other suitable isolation materials. According to other embodiments, an isolation material may be filled in the first trenches to form first isolation layer, after that, strip-shaped active zones are etched to form multiple second trenches in the strip-shaped active zones; and the second trenches are then filled with the isolation material to form second isolation layer. The first isolation layer and the second isolation layer form the isolation layer. It should be noted that, as shown in FIG. 2, the active areas 202 and the semiconductor substrate 201 are separated by a dotted line for ease of distinguishing the active areas 202 from the semiconductor substrate 201. According to the embodiment, the multiple active areas 202 are arranged in the semiconductor substrate 201 in a staggered mode in the first direction.

According to other embodiments, the active areas 202 may be formed by adopting an epitaxial process or other suitable process.

A word line dielectric layer is further formed between word lines 204 and the semiconductor substrate 201. According to an embodiment, the process for forming word lines 204 includes the following operations. A mask layer (not shown in the drawings) covering active areas 202 and the isolation layer 203 is formed. Multiple openings extending in a second direction are formed in the mask layer. Each opening expose part surfaces of the corresponding multiple active areas 202 and the isolation layer 203 between the active areas 202. Each active area is provided with two openings. The two openings divide each active area 202 into a drain region 202b between the two word lines 204 and source regions 202a respectively outside the word lines 204. The active areas 202 and corresponding part of the isolation layer on two sides of each of the active areas 202 are etched through the openings to form two word line trenches in each active area 202 and the isolation layer 203 on two sides of the active area 202. A word line dielectric layer is formed on the side surfaces and the bottom surfaces of the word line trenches. The word lines 204 filling the word line trenches are formed on the word line dielectric layers. The surfaces of the word lines 204 are lower than the surfaces of the source regions 202a and the drain regions 202b.

A first acute angle α is formed between the active areas (the first direction) and the word lines (the second direction). According to an embodiment, the first acute angle α ranges from 60 degrees to 75 degrees.

According to an embodiment, the material of the word line dielectric layer may be silicon oxide or high-K dielectric material. The material of word lines 204 may be polysilicon or metals.

According to an embodiment, isolation protective layers 205 are previously formed on the surfaces of the word lines 204. The surfaces of the isolation protective layers 205 may be flush with the surface of a semiconductor substrate 201 or slightly higher or slightly lower than the surface of the semiconductor substrate 201. The isolation protective layers 205 protect the word lines from being exposed by etching through when a hard mask layer is subsequently formed on the semiconductor substrate 201, openings are formed in the hard mask layer and trenches are formed in drain regions. By doing so, drain current or short circuit between BLCs formed in the trenches and the word lines are prevented; on the other hand, even if the positions of the trenches are partially offset when the trenches are formed, the isolation protective layers 205 can define the positions of the openings so that the bottoms of the openings can still expose the surfaces of the corresponding drain regions, and the trenches still can be formed in the drain regions and the BLCs can still be formed in the trenches. The material of the isolation protective layers 205 is different from that of the lowest layer of the hard mask layer formed subsequently. According to an embodiment, the material of the isolation protective layers 205 may be silicon nitride.

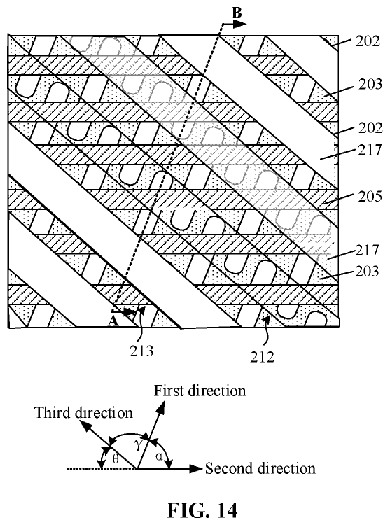

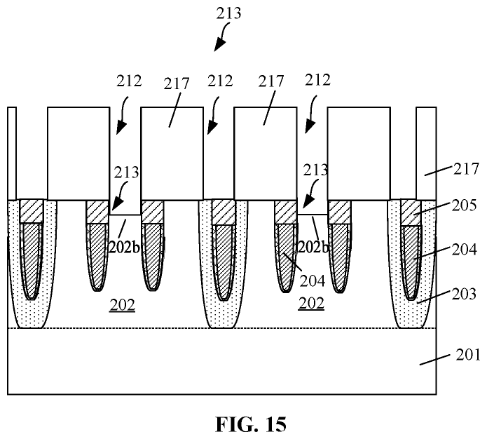

With reference to FIG. 14 and FIG. 15, FIG. 15 illustrates a schematic diagram from cross-sectional view of FIG. 14 along a cutting line AB. Multiple parallel mask patterns 217 extending in a third direction are formed on a semiconductor substrate 201 by adopting self-aligned multi-patterning. Openings 212 are arranged between adjacent mask patterns 217 and expose the surfaces of drain regions 202b and corresponding part of the isolation layer 203 (and isolation protective layers 205) in the third direction.

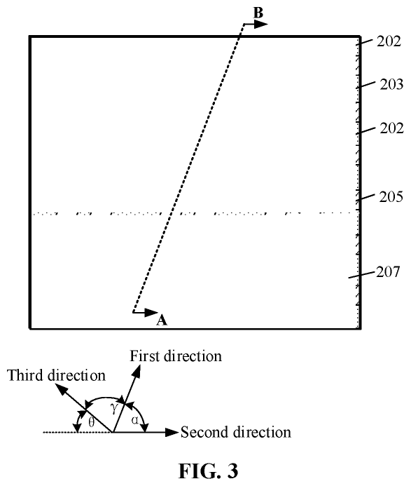

The specific process for forming multiple parallel mask patterns 217 extending in the third direction on a semiconductor substrate 201 by adopting self-aligned multi-patterning will be described in detail below with reference to FIGS. 3 to 14.

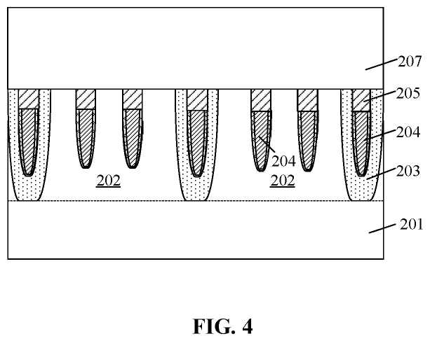

With reference to FIG. 3 and FIG. 4, FIG. 3 a structure further processed based on that in FIG. 1, and FIG. 4 illustrates a schematic structural diagram from cross-sectional view of FIG. 3 along a cutting line AB. A hard mask layer 207 is formed on the semiconductor substrate 201.

The hard mask layer 207 may be a single layer or a multi-layer stacking structure. According to the embodiment, the hard mask layer 207 is a multi-layer stacking structure. The hard mask layer 207 may include a first silicon oxide layer, a first silicon nitride layer on the first silicon oxide layer, a polysilicon layer on the first silicon nitride layer, a second silicon oxide layer on the polysilicon layer, and a second silicon nitride layer on the second silicon oxide layer.

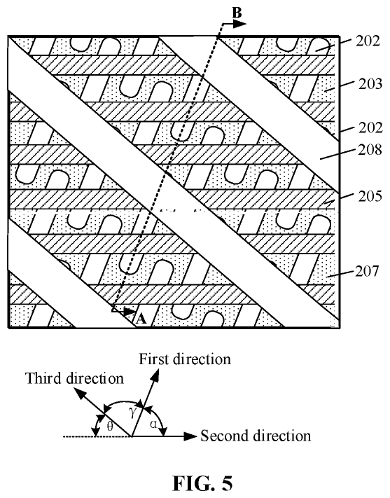

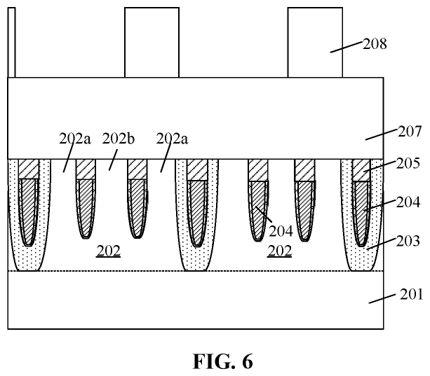

With reference to FIG. 5 and FIG. 6, FIG. 5 illustrates a structure further processed based on that in FIG. 3, and FIG. 6 illustrates a schematic structural diagram from cross-sectional view of FIG. 5 along a cutting line AB. Multiple parallel first patterns 208 extending in the third direction are formed on the hard mask layer 207.

The multiple first patterns are separated and parallel to each other. For example, one of the first patterns 208 covers one source region 202a of each of multiple active areas 202 in the third direction (such as the source region in the positive direction of each of the active areas in the first direction) and a corresponding word line adjacent to the source region. The other source region of each of active areas and the corresponding word line are not covered by the first patterns 208.

The material of the first patterns 208 is different from that of a subsequently formed side wall material layer. The material of the first patterns 208 may be one or more of silicon nitride, silicon oxynitride, silicon carbide nitride, polysilicon, silicon oxide, amorphous silicon, or amorphous carbon. According to the embodiment, the material of the first patterns 208 is silicon nitride.

According to an embodiment, the process for forming first patterns 208 includes the following operations. A first pattern material layer is formed on a hard mask layer 207. A patterned photoresist layer is formed on the first pattern material layer. The first pattern material layer is etched by taking the patterned photoresist layer as a mask to form multiple parallel first patterns 208 extending in the third direction on the hard mask layer 207.

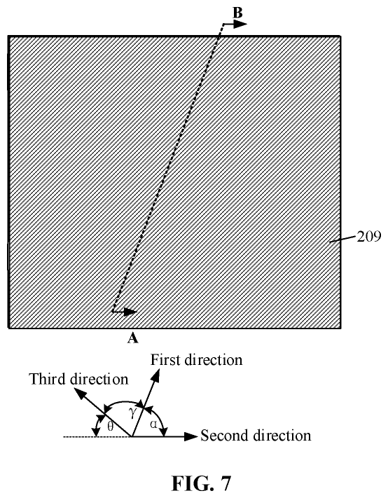

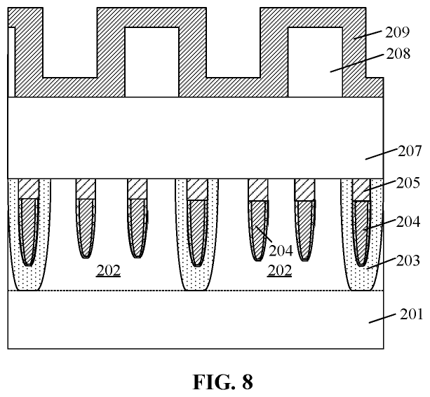

With reference to FIG. 7 and FIG. 8, FIG. 7 illustrates a structure further processed based on that in FIG. 5, and FIG. 8 illustrates a schematic structural diagram from cross-sectional view of FIG. 7 along a cutting line AB. A side wall material layer 209 is formed on the surfaces of the tops and side walls of the first patterns 208 and the surfaces of the hard mask layer 207 between the adjacent first patterns 208.

The material of the side wall material layer 209 is different from that of the first patterns 208. The material of the side wall material layer 209 may be one or more of silicon nitride, silicon oxynitride, silicon carbide nitride, polysilicon, silicon oxide, amorphous silicon, or amorphous carbon. According to the embodiment, the material of the side wall material layer 209 is silicon oxide.

The side wall material layer 209 may be formed by adopting an atomic layer deposition process, atmospheric pressure chemical vapor deposition (APCVD), plasma enhanced chemical vapor deposition (PECVD), thermal chemical vapor deposition (thermal CVD), high-density plasma chemical vapor deposition (HDPCVD), or other suitable processes.

The thickness of the side wall material layer 209 determines the width (or size) of subsequently formed openings between mask patterns and the width (or size) of trenches formed in drain regions. The thickness of the side wall material layer 209 is adjustable. For example, the thickness of the corresponding side wall material layer 209 needs to be relatively large when the subsequently formed openings between the mask patterns are required to expose the entire surfaces of the drain regions; and the thickness of the side wall material layer 209 may be small when the subsequently formed openings between the mask patterns are required to expose only part of the surfaces of the drain regions.

The thickness of the side wall material layer 209 is smaller than the spacing between adjacent first patterns 208. According to a specific embodiment, the thickness of the side wall material layer 209 is smaller than, equal to, or slightly larger than the size of drain regions along a direction perpendicular to the third direction.

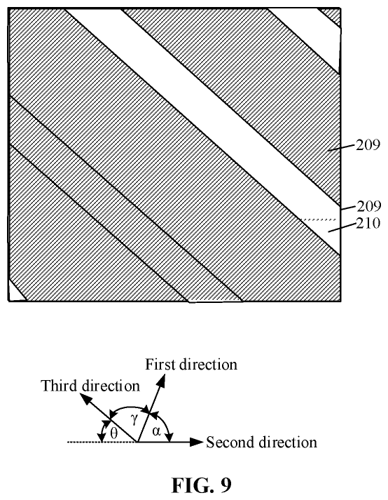

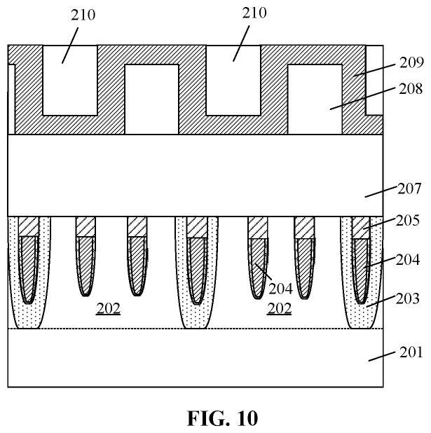

With reference to FIG. 9 and FIG. 10, FIG. 9 illustrates a structure further processed based on that in FIG. 7, and FIG. 10 illustrates a schematic structural diagram from cross-sectional view of FIG. 9 along a cutting line AB. Second patterns 210 are formed on the side wall material layer 209. The second patterns fill up the spaces between the first patterns 208.

The material of the second patterns 210 is different from that of the side wall material layer 209. The material of the second patterns 210 may be one or more of silicon nitride, silicon oxynitride, silicon carbide nitride, polysilicon, silicon oxide, amorphous silicon, or amorphous carbon. According to the embodiment, the material of the second patterns 210 is silicon nitride.

According to an embodiment, the process for forming second patterns 210 includes the following operations. A second pattern material layer is formed on the side wall material layer 209. The second pattern material layer fills up the spaces between the first patterns 208. The part of the second pattern material layer on the surface of the side wall material layer 209 higher than the top surfaces of the first patterns 208 is removed by planarization to form the second patterns 210 on the surfaces the side wall material layer 209 between the first patterns 208. The planarization is conducted by chemical mechanical polishing).

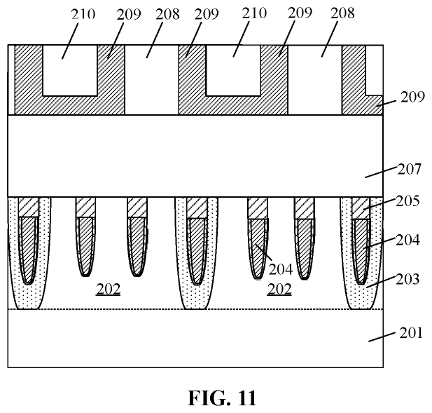

According to another embodiment, with reference to FIG. 11, after planarization is conducted to remove the part of the second pattern material layer on the surface of a side wall material layer 209 higher than the top surfaces of the first patterns 208, the planarization process is continued to remove the part of the side wall material layer and part of the second pattern material layer, which are higher than the top surfaces of the first patterns 208, so as to form second patterns 210. The retained part of the side wall material layer 209, between the side walls of the first patterns 208 and the side walls of the second patterns 210, serves as side walls. In the subsequent process, by removing the side walls, openings exposing the surfaces of the hard mask layer may be formed between the first patterns 208 and the second patterns 210. The hard mask layer 207 is continued to be etched through the openings, so that the bottoms of the openings expose the surfaces of multiple drain regions and corresponding part of the isolation layer in the third direction. The exposed drain regions are etched through the openings to form trenches in the drain regions. Therefore, the side walls define the width or feature sizes of the trenches subsequently formed in the drain regions, and define the positions of the trenches. As bit line contact structures are subsequently formed in the trenches, the side walls further define the width or feature size and positions of the bit line contact structures. The thickness of the side wall material layer 209 formed by deposition can be very small, the width or feature size of the bit line contact structures can thus be very small. In addition, the first patterns 208 and the second patterns 210 can be formed by photoetching and etching for one time (only during the first patterns 208 are formed). Because the width and feature size of the first patterns 208, which are not limited by the minimum beam width of photoetching, are relatively large, the first patterns 208 can be formed with accurate positions and high accuracy. On the other hand, the side wall material layer (side walls) is formed on the surfaces of the side walls of the first patterns by a deposition process in a self-aligned mode, so that the position accuracy of the formed side wall material layer (side walls) is relatively high and the surface roughness is relatively low. Accordingly, the position accuracy of the bit line contact structures is relatively high and the surface roughness is relatively low, thereby improving the performance of a memory device and reducing the process cost.

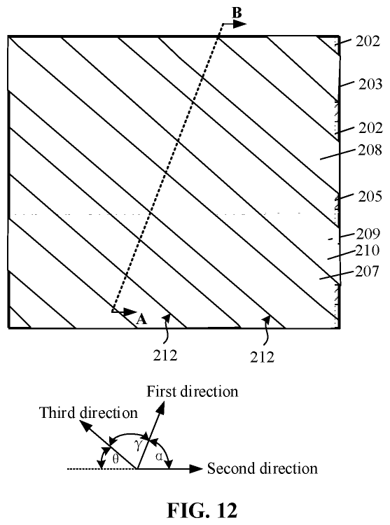

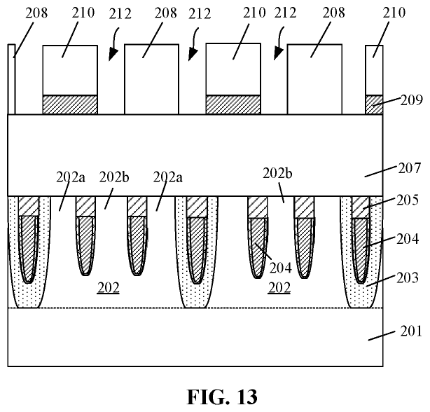

With reference to FIG. 12 and FIG. 13, FIG. 12 illustrates a structure further processed based on that in FIG. 9, and FIG. 13 illustrates a schematic structural diagram from cross-sectional view of FIG. 12 along a cutting line AB. Part of the side wall material layer, on the tops of the first patterns 208 and between the first patterns 208 and the second patterns 210, is removed. Openings 212 are formed between the first patterns 208 and the second patterns 210. The openings 212 are positioned above multiple drain regions and corresponding part of the isolation layer in the third direction.

The part of the side wall material layer (side walls), on tops of the first patterns 208, may be removed by adopting a chemical mechanical polishing process. The part, between the first patterns 208 and the second patterns 210 may be removed by adopting an anisotropic dry etching process.

Self-aligned multi-patterning is adopted to form multiple first patterns 208 and multiple second patterns 210, which are alternately distributed in parallel, on the hard mask layer 207, such that the width or feature size of the openings 212 between adjacent first patterns 208 and second patterns 210 can be relatively small and the surface roughness is relatively low. When the hard mask layer 207 and drain regions under the openings 212 are subsequently etched through the openings 212 and trenches are formed in the drain regions, the width or feature size of the trenches formed in the drain regions is relatively small and the surface roughness is relatively low. Thus, the width or feature size of the bit line contact structures formed in the trenches is relatively small and the surface roughness is relatively low, thereby improving the performance of the memory device.

The formed multiple first patterns 208 and second patterns 210 which are alternately distributed in parallel extend in the third direction. Also, the openings 212 between the first patterns 208 and second patterns 210 extend in the third direction. A second acute angle γ is formed between the third direction and the first direction. In other words, a second acute angle γ is formed between the extending direction of the mask patterns (first patterns 208 and second patterns 210) and the extending direction of the active areas 202. A third acute angle θ is formed between the third direction and the second direction. In other words, a third acute angle θ is formed between the extending direction of the mask patterns (first patterns 208 and second patterns 210) and the extending direction of the word lines 204. The second acute angle γ is larger than the first acute angle α and the third acute angle θ. The sum of the first acute angle α, the second acute angle γ and the third acute angle θ is 180 degrees. By doing so, the angle between the extending direction of the active areas 202 and the extending direction of the openings 212 is sufficiently large. When the hard mask layer 207 and the drain regions are subsequently etched through the openings 212, and the trenches 213 whose width and positions correspond to the openings 212 are formed in the drain regions (with reference to FIG. 14 and FIG. 15), the trenches 213 (with reference to FIG. 14 and FIG. 15) of the same width or same feature size can expose sufficiently large areas of the drain regions 202b. Therefore, the width or feature size of the trenches 213 and the bit line contact structures formed in the trenches 213 can be more flexible, capacitance regions (source regions 202a and corresponding regions above the source regions 202a) are protected from etching when the openings 212 and the trenches 213 are formed, and the openings 212 and the trenches 213 can be kept relatively small in width or feature size.

According to a specific embodiment, the first acute angle α ranges from 60 degrees to 75 degrees, and may be 60 degrees, 61 degrees, 62 degrees, 63 degrees, 64 degrees, 65 degrees, 66 degrees, 67 degrees, 68 degrees, 69 degrees, 70 degrees, 71 degrees, 72 degrees, 73 degrees, 74 degrees, 75 degree. The second acute angle γ ranges from 65 degrees to 80 degrees, and may be 65 degrees, 66 degrees, 67 degrees, 68 degrees, 69 degrees, 70 degrees, 71 degrees, 72 degrees, 73 degrees, 74 degrees, 75 degrees, 76 degrees, 77 degrees, 78 degrees, 79 degrees, 80 degrees, 81 degrees, 82 degrees, 83 degrees, 84 degrees, 85 degrees. The third acute angle θ ranges from 35 degrees to 45 degrees, and may be 35 degrees, 36 degrees, 37 degrees, 38 degrees, 39 degrees, 40 degrees, 41 degrees, 42 degrees, 43 degrees, 44 degrees, 45 degrees. By the foregoing specific angle setting, the flexibility of the width or feature size of trenches 213 and bit line contact structures formed in the trenches 213 is further improved, thereby better protecting capacitance regions from etching when openings 212 and the trenches 213 are formed, and making the width or feature size of the openings 212 and the trenches 213 smaller.

With reference to FIG. 14 and FIG. 15, FIG. 14 illustrates a structure further processed based on that in FIG. 12, and FIG. 15 illustrates a schematic structural diagram from cross-sectional view of FIG. 14 along a cutting line AB. The hard mask layer 207 is etched through the openings 212 by taking the first patterns 208 and second patterns 210, which are alternately distributed in parallel, as a mask (with reference to FIG. 13), such that the bottoms of the openings 212 expose the surfaces of the multiple drain regions 202b and corresponding part of the isolation layer 203 (and isolation protective layers 205) in the third direction. The retained part of the hard mask layer, on two sides of the openings 212, is adjacent mask patterns 217. The drain regions 202b and the corresponding part of the isolation layer 203 are etched through the openings 212 by taking the parallel mask patterns 217 as a mask. Multiple parallel trenches 213 are formed in the drain regions 202b and the corresponding part of the isolation layer 203.

The hard mask layer 207 is etched by an anisotropic dry etching process. When the hard mask layer 207 is etched through the openings 212, and the bottoms of the openings 212 expose the surfaces of multiple drain regions 202b and the corresponding part of the isolation layer 203 (and isolation protective layers 205) in the third direction, the etching rate of the active areas (drain regions 202b) and the hard mask layer 207 is larger than that of the isolation protective layers 205. Specifically, the etching selection ratio of the hard mask layer relative to the isolation protective layers is (5:1) to (15:1), so that the etching of the isolation protective layers 205 is small or negligible when the hard mask layer is formed, the formed trenches 213 thus do not expose the word lines 204.

According to an embodiment, when trenches 213 are formed, the etching selection ratio of active areas (drain regions 202b) relative to isolation protective layers 205 is (5:1) to (15:1), so that etching of the isolation protective layers 205 is small or negligible when the trenches 213 are formed, the formed trenches 213 thus do not expose the word lines 204.

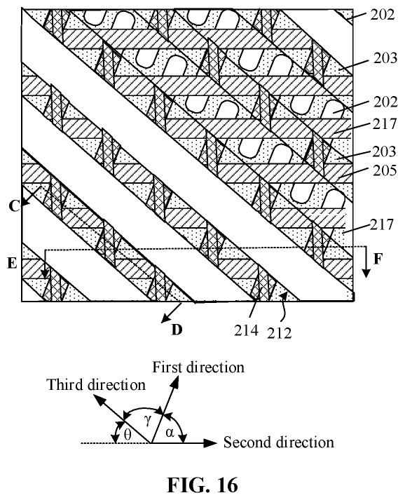

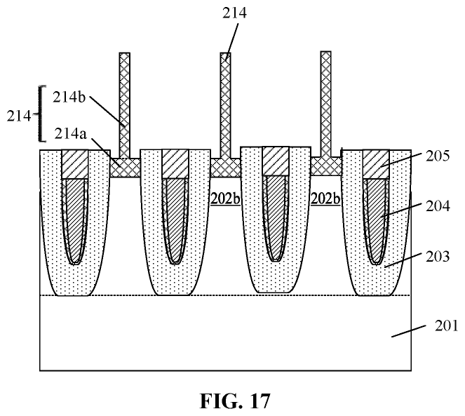

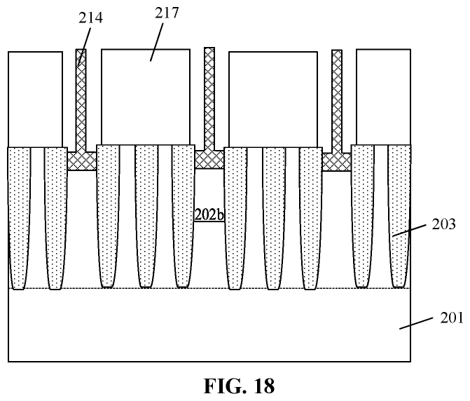

With reference to FIG. 16, FIG. 17, and FIG. 18, FIG. 16 illustrates a structure further processed based on that in FIG. 14, and FIG. 17 illustrates a schematic structural diagram from cross-sectional view of FIG. 16 along a cutting line CD. Conductive layers are filled in the trenches 213 (with reference to FIG. 15) to form strip-shaped bit line contact structures. The strip-shaped bit line contact structures are divided into multiple BLCs 214 connected to the corresponding drain regions 202b.

The material of the conductive layers is doped polysilicon such as polysilicon doped with N-type doping ions or metals such as one or more of W, Al, Cu, Ti, Ag, Au, Pt or Ni. The surfaces of the conductive layers may be flush with or higher than the surfaces of the active areas 202. According to an embodiment, conductive layers are filled in trenches 213 in drain regions 202b and in openings 212 between the mask patterns 217, that is, the strip-shaped bit line contact structures are form not only in the trenches 213, but also in the openings 212.

The strip-shaped bit line contact structures are divided by adopting an etching process, so as to form BLCs 214. Each formed BLC 214 includes a first part 214a and a second part 214b positioned on the first part 214a. The first parts 214a are embedded in the trenches formed in the drain regions 202b. The second parts 214b protrude from the surfaces of the first parts 214a. The second parts 214b extend in a direction perpendicular to the second direction. The width of the second parts 214b in the second direction (or third direction) is smaller than that of the first parts 214a in the second direction (or third direction). Therefore, the relatively large-sized first parts 214a are embedded in the drain regions 202b to maintain relatively large contact areas between the BLCs 214 and the drain regions 202b, thereby reducing the resistance. When the relatively small-sized second parts 214b are subsequently connected to formed bit lines, the size of the bit lines can also be relatively small, which can improve the integration and reduce the stray capacitance between adjacent BLCs 214. According to a specific embodiment, when strip-shaped bit line contact structures are divided, a patterned mask layer needs to be firstly formed on a substrate. The mask layer is provided with multiple openings extending in a direction perpendicular to the second direction. The openings expose bit line contact structures (conductive layers) on two sides of multiple drain regions distributed in a direction perpendicular to the second direction. The bit line contact structures (conductive layers) on the isolation layer 203 and the isolation protective layers 205 are removed by etching through the openings, and then part of the bit line contact structures (conductive layers) in the active areas may be further etched away to form BLCs 214.

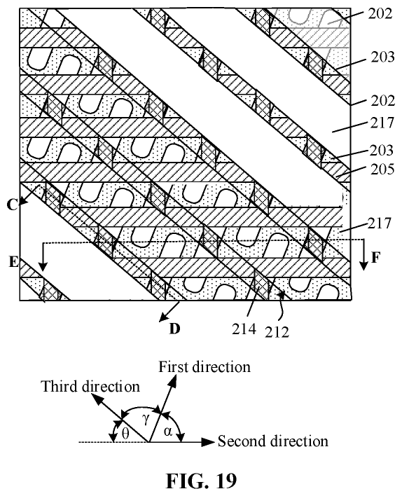

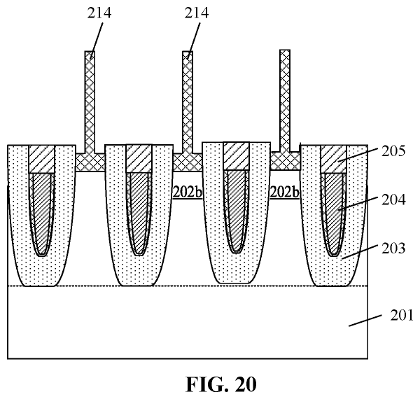

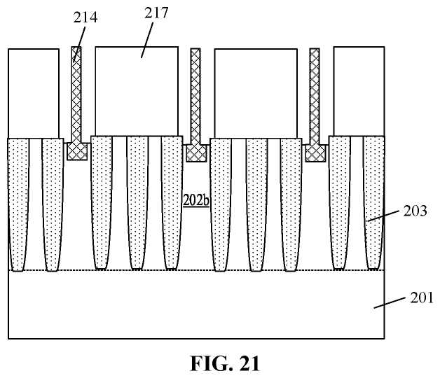

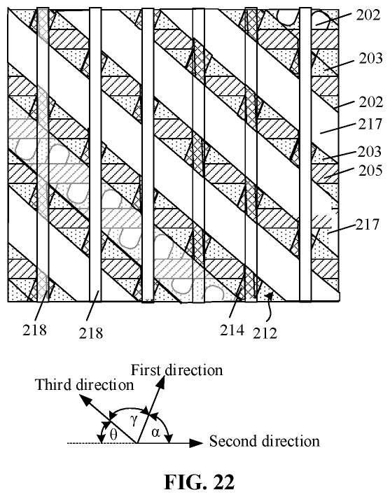

FIG. 16, FIG. 17, and FIG. 18 illustrate the BLCs 214 formed when the size of the openings 212 between the mask patterns 217 and the trenches formed in the drain regions 202b is relative large. FIG. 19, FIG. 20, and FIG. 21 illustrate the BLCs 214 formed when the size of the openings 212 between the mask patterns 217 and the trenches formed in the drain regions 202b is relative small. With reference to FIG. 22, after the BLCs 214 are formed, the method further includes the operation that bit lines 218 connecting multiple BLCs 214 are formed in a direction perpendicular to the second direction.

According to an embodiment, the process for forming bit lines 218 includes the following operations. An interlayer dielectric layer (not shown in the drawings) is formed on a semiconductor substrate. Multiple parallel openings are formed in the interlayer dielectric layer. Each opening extends in a direction perpendicular to the second direction, and exposes part of the surface of each BLC 214 arranged in the direction perpendicular to the second direction. The bit lines 218 are formed.

With reference to FIG. 14 and FIG. 15, an embodiment of the disclosure further provides a memory device, including a semiconductor substrate 201 and multiple parallel mask patterns 217.

Multiple separate active areas 202 extending in a first direction are formed in the semiconductor substrate 201. The active areas 202 are isolated with each other by an isolation layer 203. Two parallel word lines 204 extend in a second direction are formed in each active area 202 and corresponding part of the isolation layer 203. Each active area 202 is divided by two word lines 204 thereof into a drain region 202b positioned between the two word lines 204 and source regions 202a respectively positioned outside the word lines 204. A first acute angle α is formed between the first direction and the second direction.

Multiple parallel mask patterns 217 extending in a third direction are formed on the semiconductor substrate 201 by adopting self-aligned multi-patterning. Openings 212 are arranged between adjacent mask patterns 217. The surfaces of multiple drain regions 202b and corresponding part of the isolation layer 203 in the third direction are exposed by the openings. The mask patterns 217 are taken as a mask for etching the drain regions 202b and the corresponding part of the isolation layer 203. Multiple trenches distributed in parallel are formed in the drain regions 202b and the corresponding part of the isolation layer 203.

According to an embodiment, a second acute angle γ is formed between the third direction and the first direction. A third acute angle θ is formed between the third direction and the second direction. The second acute angle γ is larger than the first acute angle α and the third acute angle θ. The sum of the first acute angle α, the second acute angle γ and the third acute angle θ is 180 degrees.

According to an embodiment, the first acute angle α ranges from 60 degrees to 75 degrees. The second acute angle γ ranges from 65 degrees to 80 degrees. The third acute angle θ ranges from 35 degrees to 45 degrees.

According to a specific embodiment, the first acute angle α is 69 degrees. The second acute angle γ is 70 degrees. The third acute angle θ is 41 degrees.

According to an embodiment, the surfaces of word lines 204 are lower than the surfaces of drain regions 202b and the source regions 202a. Isolation protective layers 205 are provided on the surfaces of the word lines 204. The surfaces of the isolation protective layers 205 are flush with or higher than the surfaces of the drain regions 202b and the source regions 202a.

According to an embodiment, the etching rate of active areas 202 is larger than that of isolation protective layers 205 when trenches are subsequently formed.

The surfaces of the formed BLCs may be flush with or higher than the surfaces of the active areas 202.

It should be noted that, the definition or description of the same or similar structures according to the embodiment (the memory device) and the foregoing embodiments (the process for forming the memory device) will not be repeated, and more specifically, the definition or description of corresponding parts according to the foregoing embodiments should be taken as reference.

Although the disclosure has been described as above with reference to preferred embodiments, it should be noted that the embodiments do not intend to limit the disclosure. It is apparent to those skilled in the art that variations and modifications may be made to the disclosure according to the foregoing methods and implementations without departing from the spirit and scope of the disclosure. Therefore, any simple variations and modifications, or equivalences thereof made to the foregoing embodiments according to the technical principle of the disclosure without departing from the technical scheme of the disclosure belong to the scope of the technical scheme of the disclosure.

1. A method for forming a memory device, comprising:
providing a semiconductor substrate, separate multiple active areas extending in a first direction are formed in the semiconductor substrate, the multiple active areas being isolated with each other by an isolation layer, parallel two word lines extending in a second direction being formed in each of the active areas and corresponding part of the isolation layer, each of the active areas being divided by the two word lines thereof into a drain region positioned between the two word lines and source regions respectively positioned outside the word lines, and a first acute angle being formed between the first direction and the second direction;
forming parallel multiple mask patterns extending in a third direction on the semiconductor substrate by adopting self-aligned multi-patterning, openings being arranged between adjacent ones of the mask patterns, and surfaces of multiple drain regions and the corresponding part of the isolation layer in the third direction being exposed by the openings;
etching the drain regions and the corresponding part of the isolation layer through the openings by taking the parallel multiple mask patterns as a mask to form parallel multiple trenches in the drain regions and the corresponding part of the isolation layer;
forming strip-shaped bit line contact structures by filling conductive layers in the trenches;
dividing the strip-shaped bit line contact structures to form multiple bitline contacts (BLCs), each of the BLCs being connected to a corresponding drain region; and
forming bit lines connecting the multiple BLCs in a direction perpendicular to the second direction.

2. The method for forming the memory device of claim 1, wherein a second acute angle is formed between the third direction and the first direction.

3. The method for forming the memory device of claim 2, wherein a third acute angle is formed between the third direction and the second direction, the second acute angle is larger than the first acute angle and the third acute angle, and wherein sum of the first acute angle, the second acute angle and the third acute angle is 180 degrees.

4. The method for forming the memory device of claim 3, wherein the first acute angle ranges from 60 degrees to 75 degrees, the second acute angle ranges from 65 degrees to 80 degrees, and the third acute angle ranges from 35 degrees to 45 degrees.

5. The method for forming the memory device of claim 4, wherein the first acute angle is 69 degrees, the second acute angle is 70 degrees, and the third acute angle is 41 degrees.

6. The method for forming the memory device of claim 3, wherein said forming parallel multiple mask patterns extending in a third direction on the semiconductor substrate by adopting self-aligned multi-patterning, openings being arranged between adjacent ones of the mask patterns, and surfaces of multiple drain regions and corresponding part of the isolation layer in the third direction being exposed by the openings comprises:
forming a hard mask layer on the semiconductor substrate;
forming parallel multiple first patterns extending in the third direction on the hard mask layer;
forming a side wall material layer on surfaces of tops and side walls of the first patterns and surfaces of the hard mask layer between adjacent ones of the first patterns;
forming second patterns on the side wall material layer, the second patterns filling up spaces between the first patterns;
removing the side wall material layer on the tops of the first patterns and between the first patterns and the second patterns to form the openings between the first patterns and the second patterns; and
etching the hard mask layer through the openings so that the surfaces of the multiple drain regions and the corresponding part of the isolation layer in the third direction are exposed by bottoms of the openings, and retained parts, on two sides of each of the openings, of the hard mask layer being the adjacent ones of the mask patterns.

7. The method for forming the memory device of claim 6, wherein surfaces of the word lines are provided with isolation protective layers, and wherein when the hard mask layer is etched through the openings, an etching rate of the drain regions and the hard mask layer is higher than an etching rate of the isolation protective layers.

8. The method for forming the memory device of claim 7, wherein when the trenches are formed, an etching selection ratio of the drain regions relative to the isolation protective layers is (5:1) to (15:1).

9. The method for forming the memory device of claim 1, wherein each of the formed BLCs comprises a first part and a second part positioned on the first part; and the first part is embedded in a trench formed in the drain region, the second part protrudes from a surface of the first part, the second part extends in the direction perpendicular to the second direction, and a width of the second part in the second direction or the third direction is smaller than a width of the first part in the second direction or the third direction.

10. A memory device formed by the method of claim 1, comprising:
the semiconductor substrate, the separate multiple active areas extending in the first direction are formed in the semiconductor substrate, the active areas being isolated with each other by the isolation layer, the parallel two word lines extending in the second direction being formed in each of the active areas and corresponding part of the isolation layer, each of the active areas being divided by the two word lines thereof into the drain region positioned between the two word lines and the source regions respectively positioned outside the word lines, and the first acute angle being formed between the first direction and the second direction; and
the parallel multiple mask patterns extending in the third direction and being formed on the semiconductor substrate, the mask patterns being formed by adopting self-aligned multi-patterning, the openings being arranged between the adjacent ones of the mask patterns, and the surfaces of the multiple drain regions and the corresponding part of the isolation layer in the third direction being exposed by the openings, and the mask patterns being taken as the mask for etching the drain regions and the corresponding part of the isolation layer to form the parallel multiple trenches in the drain regions and the corresponding part of the isolation layer.
